(19) United States
(12) Patent Application Publication
(10) Pub. No.: US 2016/0054418 A1
(43) Pub. Date: Feb. 25, 2016

(54) A METHOD FOR K-SPACE SAMPLING

(71) Applicant: PHILIPS GMBH, Hamburg (DE)

(72) Inventors: MARIYA IVANOVA DONEVA, EINDHOVEN (NL); MICHAEL GUNTER HELLE, EINDHOVEN (NL); PETER BOERNERT, EINDHOVEN (NL)

(21) Appl. No.: 14/779,023

(22) PCT Filed: Mar. 7, 2014
(86) PCT No.: PCT/IB2014/059513

§ 371 Date: Sep. 22, 2015

Related U.S. Application Data
(60) Provisional application No. 61/804,220, filed on Mar. 22, 2013.

(51) Int. Cl. G01R 33/561; G01R 33/48

(52) U.S. Cl. CPC G01R 33/5611; G01R 33/4818

(57) ABSTRACT

The present invention relates to a magnetic resonance imaging MRI system (100) for acquiring magnetic resonance data from a target volume in a subject (118), the magnetic resonance imaging system (100) comprises: a memory (136) for storing machine executable instructions; and a processor (130) for controlling the MRI system (100), wherein execution of the machine executable instructions causes the processor (130) to: determine an energy distribution (301-305) over a k-space domain of the target volume; receive a reduction factor representing a degree of under-sampling of the k-space domain; derive from the energy distribution (301-305) and the received reduction factor a sampling density function; derive from the sampling density function an energy dependent sampling pattern of the k-space domain; control the MRI system (100) to acquire under-sampled k-space data using a pulse sequence that samples the k-space domain along the derived sampling pattern; apply a compressed sensing reconstruction to the acquired under-sampled data to reconstruct an image of the target volume.

### TECHNICAL FIELD OF THE INVENTION

The invention relates to relates to magnetic resonance imaging, in particular to a method for k-space sampling.

### BACKGROUND OF THE INVENTION

With recent advances in medical imaging, interest in accelerated MRI scans has increased. MRI scans may be accelerated using efficient k-space sampling, parallel imaging, or compressed sensing methods.

Compressed sensing relies on incoherent sampling, which in MRI is realized by the irregular sampling of k-space either via pseudo-random selection of phase encoding lines in Cartesian sampling or by applying non-Cartesian trajectories. Most images are not uniformly sparse over all frequencies but may have dense low frequency information and sparse high frequency information (details, edges). This is also reflected by the fact that often most of the signal energy is concentrated in the k-space center and decreases toward the k-space periphery.

Lustig M, Donoho D, Pauly J. Magn Reson Med 2007; 58:1182-95 discloses a method for the application of compressed sensing for rapid MR imaging.

### SUMMARY OF THE INVENTION

Various embodiments provide for an improved method of operating a magnetic resonance imaging MM system, an improved computer program product and an improved magnetic resonance imaging MRI system as described by the subject matter of the independent claims. Advantageous embodiments are described in the dependent claims.

In one aspect, the invention relates to a magnetic resonance imaging MRI system for acquiring magnetic resonance data from a target volume in a subject, the magnetic resonance imaging system comprising a memory for storing machine executable instructions; and a processor for controlling the MRI system, wherein execution of the machine executable instructions causes the processor to: determine an energy distribution over a k-space domain of the target volume; receive a reduction factor representing a degree of under-sampling of the k-space domain; derive from the energy distribution and the received reduction factor a sampling density function; derive from the sampling density function an energy dependent sampling pattern of the k-space domain; control the MRI system to acquire under-sampled k-space data using a pulse sequence that samples the k-space domain along the derived sampling pattern; apply a compressed sensing reconstruction to the acquired under-sampled data to reconstruct an image of the target volume.

The sampling density function may be obtained from the energy distribution in accordance with a normalization condition. The normalization condition may require that the integral of the sampling density function over the k-space domain is equal to the requested number of samples=(total number of samples at Nyquist sampling)/(total reduction factor).

The sampling density function may be used to derive the sampling density in the k-space domain. This may be done for example for a given k-space region or interval in the k-space domain by using the sampling density function integral in said interval which may be equal to (number of samples in the interval at Nyquist sampling)/(local reduction factor). The local reduction factor (i.e. sampling density) is the reduction factor to be used for under-sampling in said k-space interval.

The energy distribution over a k-space domain (or k-space energy distribution) is the distribution of energy values at each sample point in the k-space domain. It may be obtained by (MR) imaging the target volume. The k-space domain may be associated with a predefined field of view (FOV) and a resolution in the image space.

The under-sampling may be carried out in different directions of the k-space domain (e.g. in ky and kz directions). The under-sampling may refer to the fact that the sampling density with which the sampling pattern is derived may be smaller than the sampling density of the Nyquist sampling.

The sampling pattern may be randomly derived using a Poisson disk sampling (and the derived sampling density values).

These features may have the advantage of providing an efficient and an accurate under-sampling pattern since they may easily adapt the under-sampling to the adequate k-space energy distribution of the target volume being imaged.

Another advantage may be that the overall scan time may be reduced since some sampling steps may be avoided. Also, an improved image quality may be provided.

According to one embodiment, the MRI system further comprises an array of receiver RF coils for parallel data acquisition at a degree of under-sampling, wherein the execution of the machine executable instructions further causes the processor to: apply a combined compressed sensing and parallel imaging reconstruction to the acquired under-sampled data to reconstruct an image of the target volume.

According to one embodiment, the parallel imaging reconstruction comprises one of a SENSE and GRAPPA reconstruction.

The SENSE reconstruction may be applied in combination with the compressed sensing reconstruction. This embodiment may be advantageous as it may provide additional under-sampling in at least one k-space direction and a higher reduction factor may be achieved. Also, the scan time may be further reduced compared to the method using compressed sensing only.

According to one embodiment, the derivation of the sampling pattern comprises splitting the sampling density function into a plurality of portions each spanning a respective k-space region; using the density function values in the plurality of k-space regions for determining a sampling density in each of the k-space regions, wherein the sampling pattern is derived using the determined sampling densities. This may provide an accurate sampling pattern.

In another example, the density values from the sampling density function may be used to derive the sampling pattern without splitting it into plurality of portions.

According to one embodiment, the array of receiver RF coils have a spatial sensitivity map determined using pre-acquired k-space data, wherein a reduction factor in at least one k-space direction is determined for an optimal value of the g-factor. When performing the acquisition of under-sampled k-space data using a pulse sequence that samples the k-space domain along the derived sampling pattern, this additional reduction factor from the parallel imaging may be used to further reduce the acquired k-space data by further under-sampling.

The coil sensitivity information may be derived from a SENSE reference scan and may be used to incorporate information of the coil geometry in the sampling density estimation.

According to one embodiment, the sampling pattern is a Cartesian pattern.

According to one embodiment, the MM system further comprises a storage for storing one or more k-space energy distributions each determined for a respective target volume of the subject, wherein the storage further stores a data structure of one or more entries, wherein each entry is indicative of a target volume identifier and a corresponding k-space space energy distribution identifier. The storage may further comprise k-space energy distributions that are determined for different applications such as black-blood, fat-only imaging etc.

According to one embodiment, the determination of the energy distribution comprises receiving a selection of the target volume, wherein the selection is indicative of the target volume identifier; reading the data structure for determining the energy distribution identifier associated with the target volume identifier; selecting from the one or more energy distributions the energy distribution associated with the energy distribution identifier.

The data structure may be for example a table having a row “energy distribution” and a column “target volume”. The reading may be performed by accessing records in the table using the energy distribution identifier (e.g. a row index) associated with the row “energy distribution” and the target volume identifier (e.g a column index) associated with the column “target volume”.

According to one embodiment, the determination of the energy distribution comprises: receiving a selection of the target volume, wherein the selection is indicative of an energy distribution; comparing the received energy distribution with the stored one or more energy distributions; selecting from the one or more energy distributions the energy distribution as a stored energy distribution matching the received energy distribution.

The comparison may be performed by calculating the ratio between the energy value of the received k-space energy distribution to the energy value of the stored k-space energy distribution at each k-space position in the k-space domain. In case, each of the resulting ratios is smaller than a predetermined threshold value e.g. a ratio=0.99 the two k-space energy distributions match each other.

This may prevent using an energy distribution e.g. from a user that may not reflect the right k-space energy behavior in the target volume.

According to one embodiment, the determination of the energy distribution comprises: generating an energy distribution over k-space of an image of the target volume using pre-acquired k-space data; comparing the generated energy distribution with the stored one or more energy distributions; selecting from the one or more energy distributions the energy distribution as a stored energy distribution matching the generated energy distribution.

This may provide an automatic method for k-space under-sampling using an adequate k-space energy distribution of the target volume. This automatic method may also be applied after receiving a selection of the target volume, wherein the selection is indicative of an energy distribution from a user to check whether the user has performed the right selection or not. If not, the user may be asked to reselect again his desired target volume, or alternatively the method may use the automatic selection instead.

According to one embodiment, the determination of the energy distribution comprises: receiving a selection of the target volume, wherein the selection is indicative of the target volume identifier; reading the data structure for determining the energy distribution identifier associated with the target volume identifier; selecting from the one or more energy distributions the energy distribution associated with the energy distribution identifier; generating an energy distribution over k-space of an image of the target volume using pre-acquired k-space data; comparing the generated energy distribution with the selected energy distribution; in case there is a match between the selected and generated energy distribution determining the energy distribution as the selected energy distribution; in case there is no match between the selected and generated energy distribution determining the energy distribution as a stored energy distribution that matches the generated energy distribution or requesting for an update of the received selection of the target volume.

For example, the pre-acquired k-space data may be obtained using a low resolution scan such as a SENSE reference scan or a localizer scan.

According to one embodiment, the stored energy distributions are obtained using k-space data that are acquired using a plurality of high resolution scans, wherein the acquired k-space data is a sampled k-space data in accordance with Nyquist sampling density.

Each k-space energy distribution in the storage may be obtained from multiple scans (as an average distribution), that may cover different subjects with different contrasts e.g. T1, T2, Proton Density etc.

Using a fully sampled k-space data may provide an accurate k-space energy distribution of the target volume.

According to one embodiment, the stored energy distributions are obtained using simulation based on a model of the target volume.

According to one embodiment, the stored k-space energy distributions are obtained using a T1 weighted image and a T2 weighted image of the target volume.

This may be done using a plurality of scans. For example each scan may produce both T1 and T2 images. The stored k-space energy distribution may be then obtained as an average of k-space energy distributions from all produced images.

This may provide a k-space energy distribution that characterizes multiple MR images of the target volume with different contrasts.

In another aspect, the invention relates to a method of operating a magnetic resonance imaging system for acquiring magnetic resonance data from a target volume in a subject, the method comprises: determining an energy distribution over a k-space domain of the target volume; receiving a reduction factor representing a degree of under-sampling of the k-space domain; deriving from the energy distribution and the received reduction factor a sampling density function; deriving from the sampling density function an energy dependent sampling pattern of k-space; controlling the Mill system to acquire under-sampled k-space data using a pulse sequence that samples k-space along the derived sampling pattern; applying the compressed sensing reconstruction to the acquired under-sampled data.

In another aspect, the invention relates to a computer program product comprising computer executable instructions to perform the method steps of the previous embodiment.

As will be appreciated by one skilled in the art, aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

Aspects of the present invention are described with reference to flowchart illustrations and/or block diagrams of methods, apparatus (systems) and computer program products according to embodiments of the invention. It will be understood that each block or a portion of the blocks of the flowchart, illustrations, and/or block diagrams, can be implemented by computer program instructions in form of computer executable code when applicable. It is further understood that, when not mutually exclusive, combinations of blocks in different flowcharts, illustrations, and/or block diagrams may be combined. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

Any combination of one or more computer readable medium(s) may be utilized. The computer readable medium may be a computer readable signal medium or a computer readable storage medium. A ‘computer-readable storage medium’ as used herein encompasses any tangible storage medium which may store instructions which are executable by a processor of a computing device. The computer-readable storage medium may be referred to as a computer-readable non-transitory storage medium. The computer-readable storage medium may also be referred to as a tangible computer readable medium. In some embodiments, a computer-readable storage medium may also be able to store data which is able to be accessed by the processor of the computing device. Examples of computer-readable storage media include, but are not limited to: a floppy disk, a magnetic hard disk drive, a solid state hard disk, flash memory, a USB thumb drive, Random Access Memory (RAM), Read Only Memory (ROM), an optical disk, a magneto-optical disk, and the register file of the processor. Examples of optical disks include Compact Disks (CD) and Digital Versatile Disks (DVD), for example CD-ROM, CD-RW, CD-R, DVD-ROM, DVD-RW, or DVD-R disks. The term computer readable-storage medium also refers to various types of recording media capable of being accessed by the computer device via a network or communication link. For example a data may be retrieved over a modem, over the internet, or over a local area network. Computer executable code embodied on a computer readable medium may be transmitted using any appropriate medium, including but not limited to wireless, wireline, optical fiber cable, RF, etc., or any suitable combination of the foregoing.

A computer readable signal medium may include a propagated data signal with computer executable code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

‘Computer memory’ or ‘memory’ is an example of a computer-readable storage medium. Computer memory is any memory which is directly accessible to a processor. ‘Computer storage’ or ‘storage’ is a further example of a computer-readable storage medium. Computer storage is any non-volatile computer-readable storage medium. In some embodiments computer storage may also be computer memory or vice versa.

A ‘user interface’ as used herein is an interface which allows a user or operator to interact with a computer or computer system. A ‘user interface’ may also be referred to as a ‘human interface device.’ A user interface may provide information or data to the operator and/or receive information or data from the operator. A user interface may enable input from an operator to be received by the computer and may provide output to the user from the computer. In other words, the user interface may allow an operator to control or manipulate a computer and the interface may allow the computer indicate the effects of the operator's control or manipulation. The display of data or information on a display or a graphical user interface is an example of providing information to an operator. The receiving of data through a keyboard, mouse, trackball, touchpad, pointing stick, graphics tablet, joystick, gamepad, webcam, headset, gear sticks, steering wheel, pedals, wired glove, dance pad, remote control, and accelerometer are all examples of user interface components which enable the receiving of information or data from an operator.

A ‘hardware interface’ as used herein encompasses an interface which enables the processor of a computer system to interact with and/or control an external computing device and/or apparatus. A hardware interface may allow a processor to send control signals or instructions to an external computing device and/or apparatus. A hardware interface may also enable a processor to exchange data with an external computing device and/or apparatus. Examples of a hardware interface include, but are not limited to: a universal serial bus, IEEE 1394 port, parallel port, IEEE 1284 port, serial port, RS-232 port, IEEE-488 port, Bluetooth connection, Wireless local area network connection, TCP/IP connection, Ethernet connection, control voltage interface, MIDI interface, analog input interface, and digital input interface.

A ‘processor’ as used herein encompasses an electronic component which is able to execute a program or machine executable instruction. References to the computing device comprising “a processor” should be interpreted as possibly containing more than one processor or processing core. The processor may for instance be a multi-core processor. A processor may also refer to a collection of processors within a single computer system or distributed amongst multiple computer systems. The term computing device should also be interpreted to possibly refer to a collection or network of computing devices each comprising a processor or processors. Many programs have their instructions performed by multiple processors that may be within the same computing device or which may even be distributed across multiple computing devices.

Magnetic resonance image data is defined herein as being the recorded measurements of radio frequency signals emitted by atomic spins by the antenna of a Magnetic resonance apparatus during a magnetic resonance imaging scan. A Magnetic Resonance Imaging (MRI) image is defined herein as being the reconstructed two or three dimensional visualization of anatomic data contained within the magnetic resonance imaging data. This visualization can be performed using a computer.

It is understood that one or more of the aforementioned embodiments of the invention may be combined as long as the combined embodiments are not mutually exclusive.

### BRIEF DESCRIPTION OF THE DRAWINGS

In the following preferred embodiments of the invention will be described, by way of example only, and with reference to the drawings in which:

FIG. 1 illustrates a magnetic resonance imaging system,

FIG. 2 shows a flowchart of a method for k-space under-sampling, and

FIG. 3 illustrates k-space energy distributions for different anatomies.

### DETAILED DESCRIPTION OF THE EMBODIMENTS

In the following, like numbered elements in the figures are either similar elements or perform an equivalent function. Elements which have been discussed previously will not necessarily be discussed in later figures if the function is equivalent.

Various structures, systems and devices are schematically depicted in the figures for purposes of explanation only and so as to not obscure the present invention with details that are well known to those skilled in the art. Nevertheless, the attached figures are included to describe and explain illustrative examples of the disclosed subject matter.

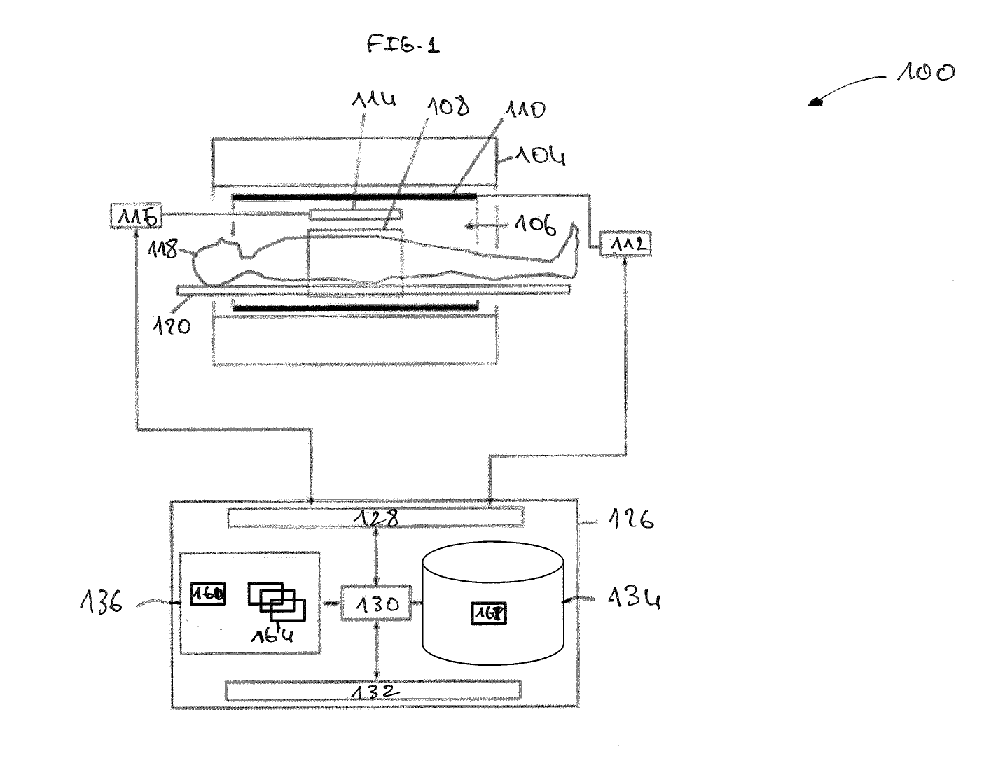

FIG. 1 illustrates an example of a magnetic resonance imaging system 100. The magnetic resonance imaging system 100 comprises a magnet 104. The magnet 104 is a superconducting cylindrical type magnet 100 with a bore 106 through it. The use of different types of magnets is also possible for instance it is also possible to use both a split cylindrical magnet and a so called open magnet. A split cylindrical magnet is similar to a standard cylindrical magnet, except that the cryostat has been split into two sections to allow access to the iso-plane of the magnet, such magnets may for instance be used in conjunction with charged particle beam therapy. An open magnet has two magnet sections, one above the other with a space in-between that is large enough to receive a subject: the arrangement of the two sections area similar to that of a Helmholtz coil. Open magnets are popular, because the subject is less confined. Inside the cryostat of the cylindrical magnet there is a collection of superconducting coils. Within the bore 106 of the cylindrical magnet 104 there is an imaging zone 108 where the magnetic field is strong and uniform enough to perform magnetic resonance imaging.

Within the bore 106 of the magnet there is also a set of magnetic field gradient coils 110 which is used for acquisition of magnetic resonance data to spatially encode magnetic spins of a target volume within the imaging zone 108 of the magnet 104. The magnetic field gradient coils 110 connected to a magnetic field gradient coil power supply 112. The magnetic field gradient coils 110 are intended to be representative. Typically magnetic field gradient coils 110 contain three separate sets of coils for spatially encoding in three orthogonal spatial directions. A magnetic field gradient power supply supplies current to the magnetic field gradient coils. The current supplied to the magnetic field gradient coils 110 is controlled as a function of time and may be ramped or pulsed.

Adjacent to the imaging zone 108 is a radio-frequency coil 114 for manipulating the orientations of magnetic spins within the imaging zone 108 and for receiving radio transmissions from spins also within the imaging zone 108. The radio frequency antenna may contain multiple coil elements. The radio frequency antenna may also be referred to as a channel or antenna. The radio-frequency coil 114 is connected to a radio frequency transceiver 116. The radio-frequency coil 114 and radio frequency transceiver 116 may be replaced by separate transmit and receive coils and a separate transmitter and receiver. It is understood that the radio-frequency coil 114 and the radio frequency transceiver 116 are representative. The radio-frequency coil 114 is intended to also represent a dedicated transmit antenna and a dedicated receive antenna. Likewise the transceiver 116 may also represent a separate transmitter and receivers.

The magnetic field gradient coil power supply 112 and the transceiver 116 are connected to a hardware interface 128 of computer system 126. The computer system 126 further comprises a processor 130. The processor 130 is connected to the hardware interface 128, a user interface 132, a library 134, and computer memory 136.

The computer memory 136 is shown as containing a control module 160. The control module 160 contains computer-executable code which enables the processor 130 to control the operation and function of the magnetic resonance imaging system 100. It also enables the basic operations of the magnetic resonance imaging system 100 such as the acquisition of magnetic resonance data. The computer memory 136 is further shown as containing a program/utility 164 having a set of program modules that contain computer-executable code which enables the processor 130 to carry out the functions and/or methodologies of embodiments of the invention as described herein.

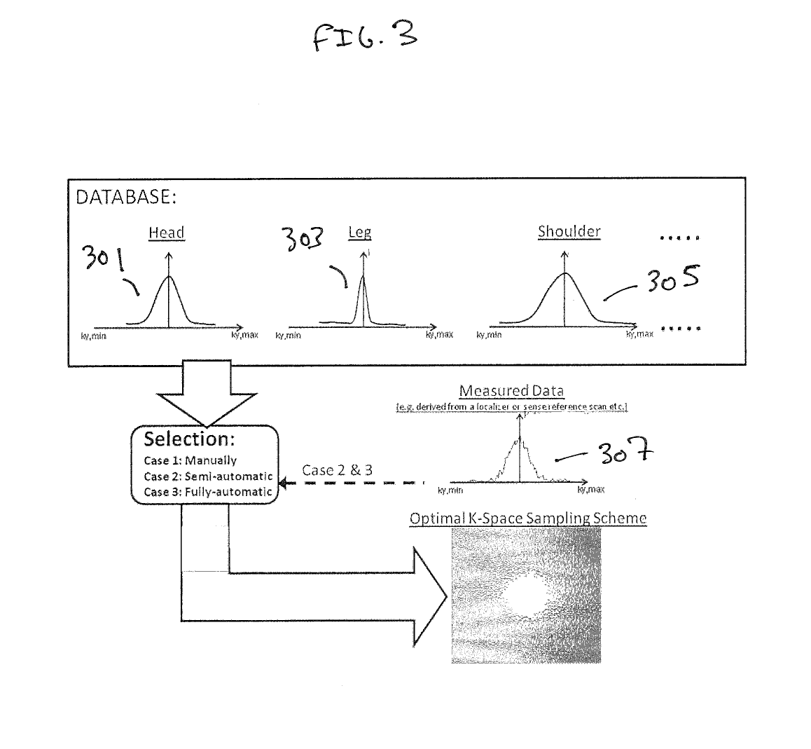

The library 134 is shown as containing energy distributions over k-space. The k-space energy distributions 168 of the library may correspond to different anatomies and applications. Illustrated examples of energy distributions for different anatomies are shown in FIG. 3. For example, for the shoulder 305 and the leg 303, the energy is differently concentrated close to the center of k-space and also decays towards the periphery of k-space in different manner.

The k-space energy distributions may be each based on multiple pre-acquired measurements to better reflect the statistical behavior of the energy distribution across several subjects and across several imaging contrasts (T1-, T2-, and proton-density weighted imaging). They may also be based on specific applications such as, for example, tagging, black-blood, high contrast MRA, fat-only imaging, etc.

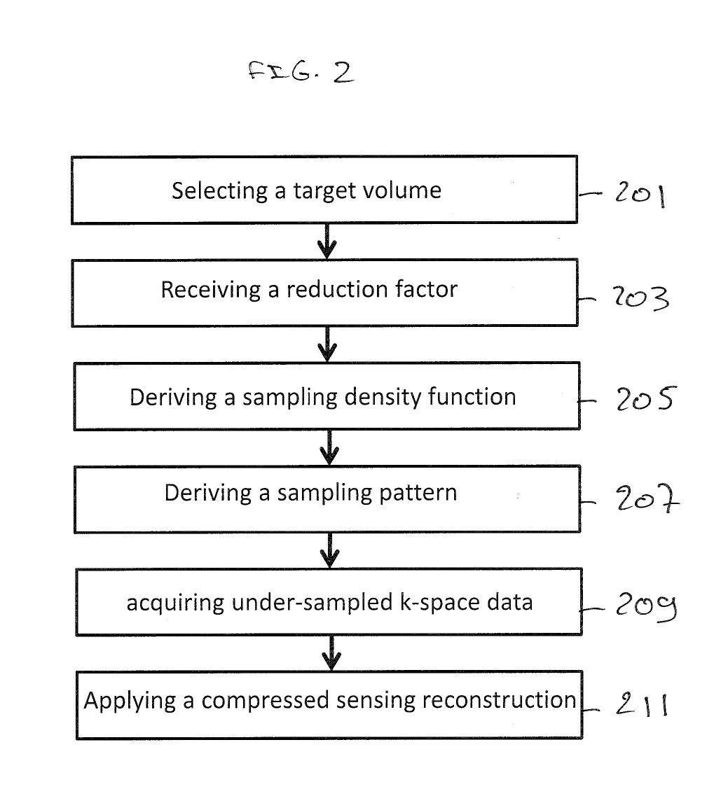

The stored k-space energy distributions 168 may be generated on the basis of simulations using anatomical models which may serve as the ground truth for any analysis procedure. In another example, the stored k-space energy 168 distributions may be generated using multiple fully sampled (i.e. Nyquist sampling) high resolution images of different anatomies, which are acquired in a previous time to the time of an accelerated (diagnostic) scan that is used for compressed sensing reconstruction as described with reference to FIG. 2

The image FOV associated with the k-space over which the energy is distributed (i.e. the stored energy distributions) may be higher than a predetermined FOV threshold value. The threshold value may be determined using the FOV that is used in the diagnostic scan. For example, the threshold value may be equal to the FOV used for the diagnostic scan that uses the library to generate an under-sampled pattern for compressed sensing. Also, the image resolution associated with the stored k-space energy distributions may be determined using the image resolution of the diagnostic scan (e.g. it may be higher than the resolution of the diagnostic scan).

The operation of the MRI system 100 will be described in details with reference to FIG. 2.

In a first example disclosed with respect to FIG. 2, the MRI system 100 may be used for imaging a target volume e.g. the head of the patient 118 e.g. in a diagnostic scan.

For that, in step 201, a selection of the target volume to be imaged may be performed. The selection may be indicative of the head and an energy distribution in k-space of the head e.g. 301 of FIG. 3.

In step 203, a reduction factor representing a degree of under-sampling of the k-space domain may be received e.g from a user of the MRI system 100. The under-sampling as described herein is performed along the phase encoding directions (e.g. along ky-kz plane), while the frequency encoding direction is usually fully sampled. Under-sampling means sampling below the Nyquist sampling. The Nyquist smapling may take into account the image FOV and resolution used for the diagnostic scan.

In step 205, a sampling density function may be derived from the energy distribution 301 and the reduction factor. For this end, the energy distribution is normalized to a probability distribution function (pdf) i.e. having an area of 1. The random selection of N_{R} samples (e.g. the number of samples at Nyquist sampling N0 divided by the received reduction factor R) without repetitions and without regarding the order can be approximated as an urn problem with repetitions but with an unknown number of iterations N>N_{R} for each location. The sampling density function at each location then corresponds to the probability that this location is selected at least once (P(S>0)). This can be calculated with the help of the inverse probability: P(S>0)=1-P(S=0). The probability that a location is selected in one iteration is given by the pdf at this location and is used to calculate the probability that this location is not selected in N repetitions (P(S=0)=(1−pdf)̂N). Therefore, the sampling density function (sdf) may be derived from the pdf using the formula sdf=1−(1−pdf).̂(N) (N is the number of samples that need to be selected with repetitions in order to end up with N_{R} samples after rejecting the repeated samples) and a normalization constraint. The normalization constraint is fulfilled using one or more iterations. In each iteration, the number of samples N is updated/increased. The normalization constraint requires that the integral of the sdf is equal to N_{R}=N0/R. That is, in the whole k-space domain, the sampling density function may have an integral of N_{R}=N0/(received reduction factor). And, in each k-space interval of the k-space domain the sampling density function may have an integral of (number of samples at Nyquist sampling for this interval)/(local reduction factor). The local reduction factor is the reduction factor to be used for under-sampling in said k-space interval.

The sampling density function is then used to derive the sampling pattern in step 207. The sampling pattern may be randomly derived with the usage of the derived sampling densities (e.g. in each k-space region covered a portion of the sampling density function) and using a Poisson disk sampling. Using the derived sampling pattern, the MRI system 100 may be controlled in step 209 to acquire under-sampled k-space data using a pulse sequence that samples the k-space domain along the derived sampling pattern.

In step 211, a compressed sensing reconstruction is then applied to the acquired under-sampled data to reconstruct an image of the head.

In a further example, the MRI system 100 may be used for imaging the target volume using a combination of SENSE imaging method and the compressed sensing method. In this case, multiple RF coils of the Mill system 100 may be used for parallel data acquisition. The combined SENSE and compressed sensing may be applied in case of a 2D and 3D Cartesian sampling.

The under-sampling method described above with reference to FIG. 2 may also be applied for combined SENSE and compressed sensing. In addition, coil sensitivity information derived from a SENSE reference scan may be used to incorporate information of the coil geometry in the sampling density estimation for the accelerated scan. This may be done before the accelerated scan starts, using pre-acquired k-space data. For example, in case of 3D Cartesian sampling under-sampling may be performed in 2D phase encoding space (k_{y}-k_{z}). The corresponding sampling density may be adapted according to the capability of the coil array to support acceleration in the two phase encoding directions. For example, a coil array arranged as 2×4 coil elements may allow higher acceleration factor in the second dimension, in which more coil elements are available. The derived sampling density of the under-sampled k-space may take into account the actual receive coil geometry and the employed acceleration factors (different for the two spatial directions). Therefore, the sampling density variation represented as concentric circles of sampling densities for a quadratic 2D phase encoding space (k_{y}-k_{z}) in case of uniform coil geometry or equal parallel imaging acceleration factors in both directions may change into a structure of concentric ellipses of sampling densities, respectively. Another approach to derive the corresponding optimal parallel imaging acceleration factors may consider the different parallel imaging encoding capabilities in the different directions (k_{y} /k_{z}) taking the underlying coil sensitivities into account. For a given total reduction parallel imaging factor Rp, the optimal distribution of reduction factors in the two phase encoding directions Rp=R_{y}*R_{z} may be obtained by using the coil sensitivity maps. This may be achieved by solving an optimization problem, minimizing the maximal g factor

g(Ry, Rz)=\sqrt{(S^{H}F^{H}MFS)⁻¹(S^{h}S)}

with respect to the two reduction factors (Ry , Rz) to find an optimum. Here S denotes the coil sensitivity maps of the coil array, F is the 2D Fourier transform, M is the sampling pattern generated with reduction factors Ry and Rz, and superscript H denotes the Hermitian operation (complex conjugate and transpose). The two reduction factors chosen this way form an input to derive the appropriate structure of concentric ellipses of sampling densities to cover the phase encoding k-space.

The obtained Ry and Rz may be used to modify the sampling density function (e.g. by scaling the sampling density function in both directions using the Ry and Rz) while the same received reduction factor is achieved and the image quality is increased.

In this case, a combined compressed sensing and SENSE reconstruction is applied to the acquired under-sampled data to reconstruct an image of the target volume.

In the following, the selection procedure of step 203 of FIG. 2 will be described in detail. An MRI protocol may start with a localizer scan of low spatial resolution as a basis for planning of all consecutive scans. In case of sensitivity encoding, a SENSE reference scan may be additionally required. For subsequent accelerated scans, in this method it is a pre-requisite to select the best matching k-space energy distribution according to the anatomical region to be examined and the specific application since the optimal sampling density function in compressed sensing is determined by the energy distribution in k-space and may therefore vary for different anatomies/applications.

The choice for the best matching k-space energy distribution for the given anatomy may be accomplished in three different ways (as illustrated in FIG. 3):

1. A manual selection may be made by the user by specifying the targeted anatomical region and thereby the corresponding k-space energy distribution before the scan starts.

2. A semi-automatic selection may be made in which the user may specify the targeted anatomical region and thereby the corresponding k-space energy distribution. An automatic comparison may be performed between a k-space energy distribution 307 of another pre-acquired scan of the same patient/subject (e.g. derived from a localizer scan, SENSE reference scan etc.) and the selected k-space energy distribution of the library. If no good match exists—for instance due to pathological or surgical alterations in the targeted volume or simply due to the wrong user selection—the user may be asked to revise his/her choice or an automatic choice may be made with respect to the best fitting k-space energy distribution from the library.

3. A fully-automatic selection may be made on the basis of pre-acquired scans of the same patient/subject (e.g. derived from a localizer scan, SENSE reference scan etc.). For the accelerated scan an automatic selection of the best matching k-space energy distribution from the library may be performed in order to ensure to fit the current anatomy. This approach may not require any user interaction. At the same time it may be less prone to selection errors and will improve the work flow.

The selection procedure described above is appropriate for standard T1/T2-weighted or PD scans, which can be well described by a single sampling density function. For other contrasts like angiography, fat only imaging, etc. a sub-selection for the specific application can be performed in a second step based on the protocol definition.

### LIST OF REFERENCE NUMERALS

100 magnetic resonance imaging system
104 magnet
106 bore of magnet
108 imaging zone
110 magnetic field gradient coils
112 magnetic field gradient coil power supply
114 radio-frequency coil
116 transceiver
118 subject
120 subject support
126 computer system
128 hardware interface
130 processor
132 user interface
134 library
136 computer memory
160 control module
164 program
168 k-space energy distributions
301-305 k-space energy distributions.

1. A magnetic resonance imaging system comprising:
a memory for storing machine executable instructions; and
a processor for controlling the magnetic resonance imaging system, wherein execution of the machine executable instructions causes the processor to:
determine an energy distribution over a k-space domain of a target volume and based on multiple pre-acquired measurements reflecting the statistical behavior of the energy distribution across several subjects and across several imaging contrasts;
receive a reduction factor representing a degree of under-sampling of the k-space domain;
derive from the energy distribution and the received reduction factor a sampling density function;
derive from the sampling density function an energy dependent sampling pattern of the k-space domain;
control the magnetic resonance imaging system to acquire under-sampled k-space data using a pulse sequence that samples the k-space domain along the derived sampling pattern;
apply a compressed sensing reconstruction to the acquired under-sampled data to reconstruct an image of the target volume.

2. The magnetic resonance imaging system of claim 1, further comprising an array of receiver radio frequency coils for parallel data acquisition at a degree of under-sampling, the array of receiver radio frequency coils having a spatial sensitivity map determined using pre-acquired k-space data, wherein the execution of the machine executable instructions further causes the processor to:
use the spatial sensitivity map to incorporate information of the coil geometry in the sampling density function and
apply a combined compressed sensing and a parallel imaging reconstruction to the acquired under-sampled data to reconstruct an image of the target volume.

3. The magnetic resonance imaging system of claim 2, wherein a reduction factor in at least one k-space direction is determined for an optimal value of the g-factor.

4. The magnetic resonance imaging system of claim 2, wherein the parallel imaging reconstruction comprises one of a SENSE and GRAPPA reconstruction.

5. The magnetic resonance imaging system of claim 1, wherein the derivation of the sampling pattern comprises:
splitting the sampling density function into a plurality of portions each spanning a respective k-space region;
using the density function values in the plurality of k-space regions for determining a sampling density in each of the k-space regions, wherein the sampling pattern is derived using the determined sampling densities.

6. The magnetic resonance imaging system of claim 1, further comprising a storage for storing one or more energy distributions wherein each energy distribution is determined for a respective target volume of at least one of the subjects, wherein the storage further stores a data structure of one or more entries, wherein each entry is indicative of a target volume identifier and a corresponding energy distribution identifier.

7. The magnetic resonance imaging system of claim 6, wherein the determination of the energy distribution comprises:
receiving a selection of the target volume, wherein the selection is indicative of the target volume identifier;
reading the data structure for determining the energy distribution identifier associated with the target volume identifier;
selecting from the one or more energy distributions the energy distribution associated with the energy distribution identifier.

8. The magnetic resonance imaging system of claim 6, wherein the determination of the energy distribution comprises:
receiving a selection of the target volume, wherein the selection is indicative of an energy distribution;
comparing the received energy distribution with the stored one or more energy distributions;
selecting from the one or more stored energy distributions the energy distribution matching the received energy distribution.

9. The magnetic resonance imaging system of claim 6, wherein the determination of the energy distribution comprises:
generating an energy distribution over k-space of an image of the target volume using pre-acquired k-space data;
comparing the generated energy distribution with the stored one or more energy distributions;
selecting from the one or more stored energy distributions the energy distribution matching the generated energy distribution.

10. The magnetic resonance imaging system of claim 6, wherein the determination of the energy distribution comprises:
receiving a selection of the target volume, wherein the selection is indicative of the target volume identifier;
reading the data structure for determining the energy distribution identifier associated with the target volume identifier;
selecting from the one or more energy distributions the energy distribution associated with the energy distribution identifier;
generating an energy distribution over k-space of an image of the target volume using pre-acquired k-space data;
comparing the generated energy distribution with the selected energy distribution;
in case there is a match between the selected and generated energy distribution determining the energy distribution as the selected energy distribution;
in case there is no match between the selected and generated energy distribution determining the energy distribution as a stored energy distribution that matches the generated energy distribution or requesting for an update of the received selection of the target volume.

11. The magnetic resonance imaging system of claim 6, wherein the stored energy distributions are obtained using k-space data that are acquired using a plurality of high resolution scans, wherein the acquired k-space data is a sampled k-space data in accordance with Nyquist sampling density.

12. The magnetic resonance imaging system of claim 6, wherein the stored energy distributions are obtained using simulation based on a model of the target volume.

13. The magnetic resonance imaging system of claim 6, wherein the stored energy distributions are obtained using a T1 weighted image and a T2 weighted image of the target volume.

14. A method of operating a magnetic resonance imaging system comprising:
determining an energy distribution over a k-space space domain of a target volume and based on multiple pre-acquired measurements reflecting the statistical behavior of the energy distribution across several subjects and across several imaging contrasts;
receiving a reduction factor representing a degree of under-sampling of the k-space domain;
deriving from the energy distribution and the received reduction factor a sampling density function;
deriving from the sampling density function an energy dependent sampling pattern of k-space;
controlling the magnetic resonance imaging system to acquire under-sampled k-space data using a pulse sequence that samples k-space along the derived sampling pattern;
applying the compressed sensing reconstruction to the acquired under-sampled data.

15. A computer program product comprising computer executable instructions to perform the method of claim 14.

16. A magnetic resonance imaging system comprising:
a memory for storing machine executable instructions; and
a processor for controlling the magnetic resonance imaging system, wherein execution of the machine executable instructions causes the processor to:
determine an energy distribution over a k-space domain of ire a target volume and based on multiple pre-acquired measurements reflecting the statistical behavior of the energy distribution across several subjects and across several imaging contrasts1 and based on specific imaging applications;
receive a reduction factor representing a degree of under-sampling of the k-space domain;
derive from the energy distribution and the received reduction factor a sampling density function;
derive from the sampling density function an energy dependent sampling pattern of the k-space domain;
control the magnetic resonance imaging system to acquire under-sampled k-space data using a pulse sequence that samples the k-space domain along the derived sampling pattern;
apply a compressed sensing reconstruction to the acquired under-sampled data to reconstruct an image of the target volume.

17. A method of operating a magnetic resonance imaging system comprising:
determining an energy distribution over a k-space domain of a target volume and based on multiple pre-acquired measurements reflecting the statistical behavior of the energy distribution across several subjects and across several imaging contrasts1and based on specific imaging applications;
receiving a reduction factor representing a degree of under-sampling of the k-space domain;
deriving from the energy distribution and the received reduction factor a sampling density function;
deriving from the sampling density function an energy dependent sampling pattern of k-space;
controlling the magnetic resonance imaging system to acquire under-sampled k-space data using a pulse sequence that samples k-space along the derived sampling pattern;
applying the compressed sensing reconstruction to the acquired under-sampled data.
